(19) United States
(12) Patent Application Publication
(10) Pub. No.: US 2025/0216731 A1
(43) Pub. Date: Jul. 3, 2025

(54) ARRAY SUBSTRATE

(71) Applicant: Guangzhou China Star Optoelectronics Semiconductor Display Technology Co., LTd., Guangzhou (CN)

(72) Inventor: Ping YU, Guangzhou (CN)

(73) Assignee: Guangzhou China Star Optoelectronics Semiconductor Display Technology Co., LTd., Guangzhou (CN)

(21) Appl. No.: 18/991,686

(22) Filed: Dec. 22, 2024

(30) Foreign Application Priority Data
Dec. 29, 2023 (CN) 202311872077.3

(51) Int. Cl. G02F 1/1362; G02F 1/1343; G02F 1/1368

(52) U.S. Cl. CPC G02F 1/136218; G02F 1/134309; G02F 1/136286; G02F 1/1368

(57) ABSTRACT

An array substrate including a substrate, a source-drain layer, a pixel electrode layer, and a common electrode layer in a stacked configuration. The source-drain layer includes a plurality of data lines. The pixel electrode layer is disposed at a side of the source-drain layer away from the substrate. The pixel electrode layer includes a plurality of pixel electrodes. The common electrode layer is disposed at a side of the pixel electrode layer away from the substrate. The common electrode layer includes a plurality of common electrodes. By setting each data line to include a first data segment disposed between two adjacent pixel electrodes, the orthographic projection of the first data segment on the substrate is not overlapped with that of the pixel electrode layer on the substrate or with that of the common electrode layer on the substrate.

### CROSS-REFERENCE TO RELATED APPLICATION

This application claims priority to and the benefit of Chinese Patent Application No. 202311872077.3, filed on Dec. 29, 2023, the disclosure of which is incorporated herein by reference in its entirety.

### TECHNICAL FIELD

The present application relates to the field of display technologies, and in particular to an array substrate.

### BACKGROUND

As people's demands increase, high refresh rate, high image quality, and low cost are increasingly becoming basic elements for high-end electronic display products in the market.

To achieve high image quality, the Fringe Field Switching (FFS) technology generates fringe electric fields through electrodes between pixels in the same plane, so that the oriented liquid crystal molecules between the electrodes and directly above the electrodes can be rotated in the plane direction, achieving high light transmittance under a wide viewing angle. However, in the liquid crystal display (LCD) panels with fringe field switching mode, there is often a large lateral parasitic capacitance between the data lines and the pixel electrodes, which is very prone to generate signal crosstalk, affecting the display effect.

### SUMMARY

An embodiment of the present application provides an array substrate for alleviating deficiencies in related technologies.

In order to realize the above functions, the technical solutions provided by the embodiments of the present disclosure are as follows.

An embodiment of the present disclosure provides an array substrate including:
a substrate;
a source-drain layer disposed at a side of the substrate, the source-drain layer including a plurality of data lines;
a pixel electrode layer disposed at a side of the source-drain layer away from the substrate, the pixel electrode layer including a plurality of pixel electrodes arranged at intervals;
a common electrode layer disposed at a side of the pixel electrode layer away from the substrate,
where each of the plurality of data lines includes a first data segment arranged between two adjacent ones of the plurality of pixel electrodes, with an orthographic projection of the first data segment on the substrate being not overlapped with an orthographic projection of the pixel electrode layer on the substrate, and the orthographic projection of the first data segment on the substrate being not overlapped with an orthographic projection of the common electrode layer on the substrate.

An embodiment of the present disclosure provides a mobile terminal, including a terminal and a display panel, the terminal body and the display panel being integrated, the display panel including an array substrate, the array substrate including:
a substrate;
a source-drain layer disposed at a side of the substrate, the source-drain layer including a plurality of data lines;
a pixel electrode layer disposed at a side of the source-drain layer away from the substrate, the pixel electrode layer including a plurality of pixel electrodes arranged at intervals;
a common electrode layer disposed at a side of the pixel electrode layer away from the substrate,
where each of the plurality of data lines includes a first data segment arranged between two adjacent ones of the plurality of pixel electrodes, with an orthographic projection of the first data segment on the substrate being not overlapped with an orthographic projection of the pixel electrode layer on the substrate, and the orthographic projection of the first data segment on the substrate being not overlapped with an orthographic projection of the common electrode layer on the substrate.

### BRIEF DESCRIPTION OF THE DRAWINGS

To more clearly illustrate the technical solutions in the embodiments of the present disclosure, the accompanying drawings to be used in the description of the embodiments will be briefly introduced below. It is obvious that the accompanying drawings described below are merely some embodiments of the present disclosure. For a person of ordinary skill in the art, other drawings can be obtained based on these drawings without the need for creative effort.

FIG. 1 is a first schematic cross-sectional diagram of a display panel according to an embodiment of the present disclosure.

FIG. 2 is an equivalent circuit diagram of a pixel structure according to an embodiment of the present disclosure.

FIG. 3 is a second schematic cross-sectional diagram of a display panel according to an embodiment of the present disclosure.

FIG. 4 is a first top view cross-sectional diagram of a display panel according to an embodiment of the present disclosure.

FIG. 5 is a second top view cross-sectional diagram of a display panel according to an embodiment of the present disclosure.

FIG. 6 is a third schematic cross-sectional diagram of a display panel according to an embodiment of the present disclosure.

### DETAILED DESCRIPTION

The technical solutions in the embodiments of the present disclosure will be clearly and completely described below in conjunction with the accompanying drawings of the embodiments of the present disclosure. It is obvious that the described embodiments are merely some of the embodiments of the present disclosure, rather than all of the embodiments. Based on the embodiments in the present disclosure, all other embodiments obtained by a person of ordinary skill in the art without making creative efforts fall within the scope of the present disclosure. In addition, it should be understood that the specific embodiments described herein are only used to illustrate and explain the present disclosure and does not intend to limit the present disclosure. In the present disclosure, unless otherwise stated, directional terms such as “upper” and “lower” generally refer to the up and down in an actual usage or operational status of a device, specifically to the directions in the figures of the accompanying drawings; while terms such as “inner” and “outer” refer to an outline of the device.

An embodiment of the present disclosure provides an array substrate. The following will be described in detail. It should be noted that the order of description of the following embodiments does not serve as a limitation on the preferred order of the embodiments.

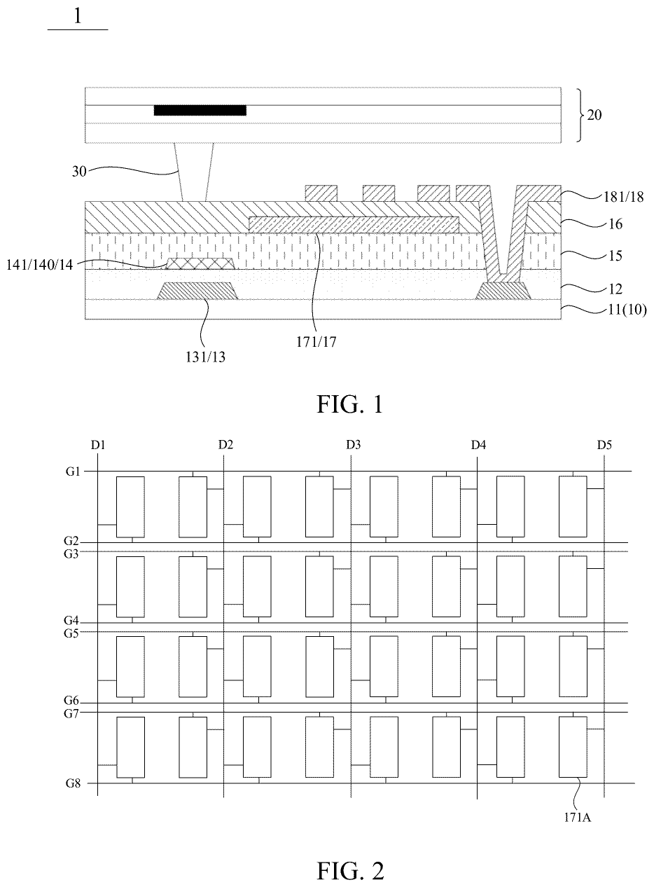

Referring to FIG. 1, FIG. 1 is a first schematic cross-sectional diagram of a display panel according to an embodiment of the present disclosure.

The present embodiment provides a display panel 1. The display panel 1 includes but is not limited to a liquid crystal display panel. The display panel 1 includes an array substrate 10 and a color film substrate 20 that are oppositely disposed, and a liquid crystal layer (not shown in the figure) and at least one support column 30 disposed between the array substrate 10 and the color film substrate 20.

The array substrate 10 includes a substrate 11, a source-drain layer 140, a pixel electrode layer 171 and a common electrode layer 181. The source-drain layer 140 is disposed on a side of the substrate 11. The source-drain layer 140 includes a plurality of data lines 141. The pixel electrode layer 171 is disposed at a side of the source-drain layer 140 away from the substrate 11. The pixel electrode layer 171 includes a plurality of pixel electrodes 171A disposed at intervals. The common electrode layer 181 is disposed at a side of the pixel electrode layer 171 away from the substrate 11.

Specifically, in an embodiment, the array substrate 10 includes a substrate 11, a first metal layer 13, a first insulating layer 12, a semiconductor layer 19, a second metal layer 14, a first passivation layer 15, a first electrode layer 17, a second passivation layer 16 and a second electrode layer 18 in a stacked configuration.

The substrate 11 may either be a rigid substrate or a flexible substrate. Under a condition that the substrate 11 is a rigid substrate, its material may be metal or glass, and under a condition that the substrate 11 is a flexible substrate, the material may include at least one of acrylic resin, methacrylic resin, polyisoprene, vinyl resin, epoxy resin, polyurethane-based resin, cellulose resin, siloxane resin, polyimide-based resin, polyamide-based resin, and the present embodiment does not make specific restrictions in this regard.

The first metal layer 13 is disposed at a side of the substrate 11. The first insulating layer 12 is disposed at a side of the first metal layer 13 away from the substrate 11. The first insulating layer 12 has strong water and oxygen barrier capabilities as well as insulating capabilities, and its material includes but is not limited to silicon oxide, silicon nitride, silicon oxynitride, etc., or a stack of a combination thereof. The second metal layer 14 is disposed at a side of the first insulating layer 12 away from the first metal layer 13. The first metal layer 13 includes a gate (not shown in the figure) and at least one scan line 131. The second metal layer 14 includes a source-drain layer 140, and the source drain layer 140 includes a source (not shown in the figure), a drain (not shown in the figure) and a plurality of data lines 141. Herein, a material of the first metal layer 13 and a material of the second metal layer 14 may be a transparent conductive material, and the transparent conductive material includes, but is not limited to, a transparent metal oxide conductive material such as indium tin oxide.

The semiconductor layer 19 includes an active layer (not shown in the figure). The active layer includes a channel portion and a source-drain contact portion arranged on both sides of the channel portion. An orthographic projection of the gate on the substrate covers an orthographic projection of the channel portion on the substrate. The source-drain contact portion includes a source contact portion and a drain contact portion, the source contact portion and the source being electrically connected, and the drain contact portion and the drain being electrically connected. Herein, the array substrate 10 includes a thin-film transistor layer (not shown in the figure). The thin-film transistor layer includes a plurality of thin-film transistors arranged in a matrix pattern. Each thin-film transistor includes conventional layers such as a gate, an active layer, a source and a drain located on the substrate 11. The present embodiment does not provide further detailed description in this regard.

The first passivation layer 15, the first electrode layer 17, the second passivation layer 16 and the second electrode layer 18 are sequentially stacked and disposed on the second metal layer 14. A material of the passivation layer 15 includes but is not limited to silicon oxide, silicon nitride, silicon oxynitride, etc. or a stack of a combination thereof. Both the first electrode layer 17 and the second electrode layer 18 may be made of a transparent conductive layer such as indium tin oxide. The first electrode layer 17 includes a plurality of pixel electrodes 171A that are separately disposed. The second electrode layer 18 includes a common electrode layer 181.

Further, each of the data lines 141 includes a first data segment 1411 disposed between two adjacent ones of the pixel electrodes 171A. At least a portion of the first passivation layer 15 is disposed between the pixel electrodes 171A and the first data segment 1411. An orthographic projection of the first data segment 1411 on the substrate 11 is not overlapped with an orthographic projection of the pixel electrode layer 171 on the substrate 11, and an orthographic projection of the first data segment 1411 on the substrate 11 is not overlapped with an orthographic projection of the common electrode layer 181 on the substrate 11.

Specifically, please refer to Table 1, which provides various parameters of a display panel provided in Embodiment 1 of the present disclosure, as well as various parameters of an existing display panel provided in Comparative Example 1.

Herein, in the Comparative Example 1, the existing display panel includes a substrate, a scan line, a first insulating layer, a data line, a pixel electrode, a second passivation layer and a common electrode in a stacked configuration. That is, compared with the display panel provided in the Embodiment 1 of the present disclosure, the existing display panel does not include a first passivation layer. Herein, performance parameters of the existing display panel and the display panel provided in the Embodiment 1 of the present disclosure were measured under same implementation conditions. For details, please refer to Table 1.

TABLE 1

| category | Comparative Example 1 | Embodiment 1 |
|---|---|---|
| Parasitic capacitance (data | 5.045 | 3.002 |
| line/pixel electrode) | | |
| Parasitic capacitance (data | 173.992 | 136.188 |
| line/common electrode) | | |
| Parasitic capacitance (thin- | 78.796 | 72.437 |
| film transistor) | | |
| Resistor/Capacitor (data line) | 0.992 | 0.82 |
| charging rate | 87% | 90% |

It should be noted that in the array substrate 10, if the pixel electrodes 171A and the data lines 141 overlap with each other, coupling will occur between the electrodes. This coupling between the electrodes will cause delays in data signals, vertical crosstalk, and degradation of image quality, including undesirable phenomena such as moiré patterns due to an increase in parasitic capacitance. Herein, the capacitance formed between the pixel electrodes 171A and the data lines 141 is an important factor in signal delays for the data lines 141. The magnitude of this capacitance may be seen in the calculation formula: C=(ε*S)/d; where C is the capacitance, ¿ is the relative dielectric constant, related to material properties, S is an overlapping area between the pixel electrodes 171A and the data lines 141, d is a distance between the pixel electrodes 171A and the data lines 141.

It can be understood that in the present embodiment, each of the data lines 141 is set to include the first data segment 1411 located between two adjacent ones of the pixel electrodes 171A. At least a portion of the first passivation layer 15 is disposed between the pixel electrodes 171A and the first data segment 1411. Moreover, the orthographic projection of the first data segment 1411 on the substrate 11 is not overlapped with the orthographic projection of the pixel electrode layer 171 on the substrate 11. This increases a spacing between the first data segment 1411 and the pixel electrode layer 171, reduces the overlapping area between the first data segment 1411 and the pixel electrode layer 171, thereby decreasing the parasitic capacitance between the data lines 141 and the pixel electrodes 171A, and improving the signal crosstalk caused by the parasitic capacitance to the pixel electrodes 171A. At the same time, the orthographic projection of the first data segment 1411 on the substrate 11 is not overlapped with the orthographic projection of the common electrode layer 181 on the substrate 11, reducing a parasitic capacitance between the data lines 141 and common electrodes 181A. This reduces delays of signals passing through the data lines 141, increases an effective charging time, and thus enhances a charging rate of the pixel electrodes 171A.

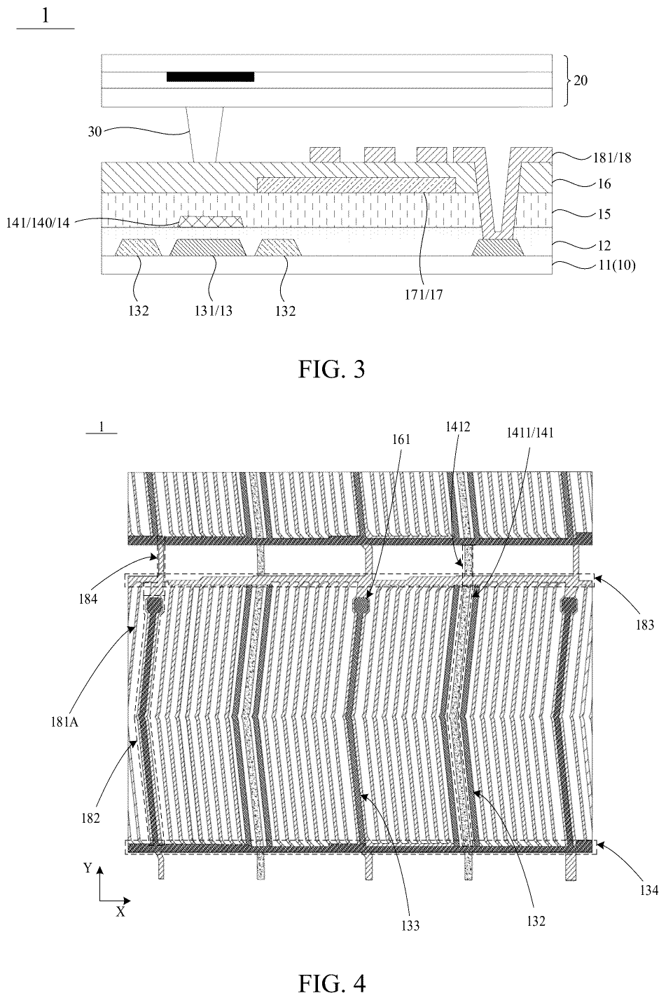

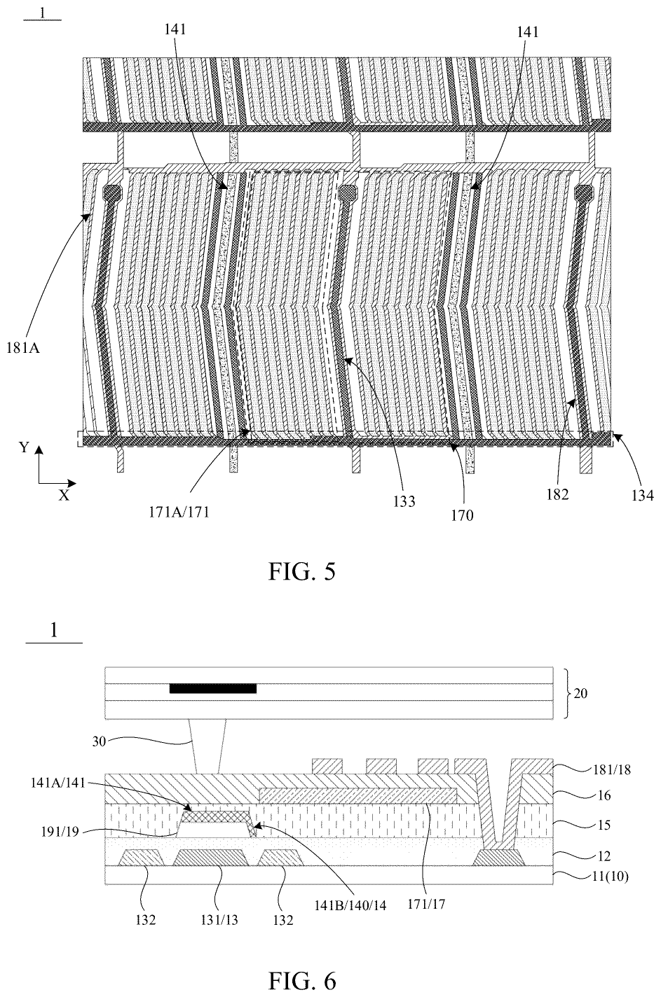

Further, please refer to FIGS. 3, 4 and 5, where FIG. 3 is a second schematic cross-sectional diagram of a display panel according to an embodiment of the present disclosure, FIG. 4 is a first top view cross-sectional diagram of a display panel according to an embodiment of the present disclosure, and FIG. 5 is a second top view cross-sectional diagram of a display panel according to an embodiment of the present disclosure.

In an embodiment, the common electrode layer 181 includes a plurality of common electrodes 181A. The common electrodes 181A include a plurality of slits. A direction of extension of the slits is parallel to a direction of extension of the data lines 141. The pixel electrode layer 171 includes a plurality of pixel electrode groups 170. Each of the pixel electrode groups 170 is disposed between two adjacent ones of the data lines 141. Each of the pixel electrode groups 170 includes two of the pixel electrodes 171A. Herein, each of the common electrodes 181A is provided corresponding to a respective one of the pixel electrodes 171A. In each of the pixel electrode groups 170, either of the pixel electrodes 171A is connected to one of the data lines 141 (for example, the two adjacent data lines 141) that is closer to the pixel electrode. That is, adjacent pixel electrodes 171A may adopt the technology of sharing of the data lines 141 to reduce the number of the data lines 141, thereby reducing a manufacturing cost of the array substrate 10. Herein, as shown in FIG. 2, which is an equivalent circuit diagram of a pixel structure according to an embodiment of the present disclosure, the present embodiment takes the pixel structure surrounded by data lines D1˜D5 and scan lines G1˜G8 as an example to illustrate the technical solution of the present disclosure.

The first metal layer 13 includes a plurality of first shielding lines 132. A direction of extension of the first shielding lines 132 is parallel to the direction of extension of the data lines 141. Herein, an orthographic projection of two adjacent ones of the first shielding lines 132 on the substrate 11 is not overlapped with an orthographic projection of one of the data lines 141 on the substrate 11, and is located on both sides of the orthographic projection of the data line 141 on the substrate 11. The first shielding lines 132 may be connected to one or more common signal.

Specifically, please refer to Table 2, which provides various parameters of a display panel provided in Embodiment 1 of the present disclosure, as well as various parameters of a display panel provided in Embodiment 2 of the present disclosure.

Herein, compared with the display panel provided in Embodiment 2 of the present disclosure, the display panel described in Embodiment 1 of the present disclosure does not include the first shielding lines. Herein, performance parameters of the display panel provided in Embodiment 1 and performance parameters of the display panel provided in Embodiment 2 were measured under same implementation conditions. For details, please refer to Table 2.

TABLE 2

| category | Embodiment 1 | Embodiment 2 |
|---|---|---|
| Parasitic capacitance (data | 3.002 | 5.057 |
| line/pixel electrode) | | |
| Parasitic capacitance (data | 136.188 | 49.792 |
| line/common electrode) | | |
| Parasitic capacitance (thin- | 72.437 | 78.469 |
| film transistor) | | |
| Resistor/Capacitor (data line) | 0.82 | 0.517 |
| charging rate | 90% | 96% |

It can be understood that in the array substrate 10 provided in the present embodiment, by adding the first shielding lines 132 made of the same material as the scan line 131 underneath the data lines 141, and connecting the first shielding lines 132 to the one or more common signals, a shielding electric field is formed in proximity of the data lines 141, which prevents liquid crystal molecules in that place from being affected by an electric field of the pixel electrodes 171A, effectively preventing leakage of light at the data lines 141. At the same time, the charging rate of the pixel electrodes 171A is enhanced, and the display quality of the panel is improved.

Further, in the present embodiment, an orthographic projection of the common electrodes 181A on the substrate 11 is not overlapped with an orthographic projection of the first shielding lines 132 on the substrate 11. This avoids the generation of an electric field between the first shielding lines 132 and the common electrode layer 181, thereby preventing any impact on the shielding effect of the data lines 141.

In an embodiment, the common electrode layer 181 further includes a plurality of first common lines 182. The first metal layer 13 includes a plurality of second shielding lines 133. Each of the first common lines 182 is provided corresponding to a respective one of the second shielding lines 133. Each of the first common lines 182 and the respective one of the second shielding lines 133 are disposed between two adjacent ones of the pixel electrodes 171A. Herein, an orthographic projection of the first common lines 182 on the substrate 11 covers an orthographic projection of the second shielding lines 133 on the substrate 11. The first common lines 182 are connected with the second shielding lines 133, respectively.

Specifically, the second shielding lines 133 is spaced and set apart from the first shielding lines 132. The first common lines 182 are disposed directly above the second shielding lines 133. The direction of extension of the second shielding lines 133 is parallel to the direction of extension of the first common lines 182, and the direction of extension of the second shielding lines 133 is parallel to the direction of extension of the data lines 141. The array substrate 10 is provided with a plurality of through-holes 161. The through-holes 161 are disposed above the second shielding lines 133. The through-holes 161 penetrates through the second passivation layer 16, the first passivation layer 15 and the first insulation layer 12 successively. The first common lines 182 are electrically connected to the second shielding lines 133 through the through-holes 161, enabling the second shielding lines 133 to receive the common signal(s) input to the first common lines 182.

In an embodiment, the first metal layer 13 further includes a third shielding line 134 extending in a first direction X. Both the first shielding lines 132 and the second shielding lines 133 extend in a second direction Y. Herein, one end of each of the first shielding lines 132 is connected to the third shielding line 134, one end of each of the second shielding lines 133 is connected to the third shielding line 134, and another end of each of the second shielding line 133 is connected to a respective one of the first common lines 182. The first direction X and the second direction Y form a predetermined angle.

It should be noted that the present embodiment takes the first direction as the X direction, the second direction as the Y direction, and the predetermined angle as a right angle to illustrate the technical solution of the present disclosure. Herein, the third shielding line 134 extends in the first direction X, while the first shielding lines 132, the second shielding lines 133, the first common lines 182 and the scan lines 131 all extend in the second direction Y.

It can be understood that in the present embodiment, one end of each of the first shielding lines 132 is connected to the third shielding line 134, and another end of each of the second shielding lines 133 is connected to the third shielding line 134, thereby interconnecting the first shielding lines 132, the second shielding lines 133 and the third shielding line 134. The common signal(s) received by the second shielding lines 133 may be transmitted to each of the first shielding lines 132 through the third shielding line 134, thus forming a shielding electric field in proximity of the data lines 141. This prevents the liquid crystal molecules at that place from being affected by the electric field of the pixel electrodes 171A when the array substrate 10 is used for the liquid crystal display panel 1, effectively preventing leakage of light at the data lines 141 and improving the display quality of the panel.

In an embodiment, each of the second shielding lines 133 is disposed between two adjacent ones of the data lines 141, with a distance from the second shielding line 133 to one of the data lines 141 being equal to a distance from the second shielding line 133 to another one of the data lines 141, i.e., the second shielding line 133 being disposed in the middle of the two adjacent data lines 141.

One of the data lines 141 is provided corresponding to two respective ones of the first shielding lines 132. For a single one of the data lines 141 and its two corresponding ones of the first shielding lines 132, an orthographic projection of two adjacent ones of the first shielding lines 132 on the substrate 11 is not overlapped with an orthographic projection of the one of the data lines 141 on the substrate 11, and is located on both sides of the orthographic projection of the data line 141 on the substrate 11, with a distance from the one of the data lines 141 to one of the first shielding lines 132 being equal to a distance from the data line 141 to another one of the first shielding lines 132, i.e., the data line 141 being disposed in the middle of the two adjacent first shielding lines 132. This allows electric currents, when present in the second shielding lines 133, to flow evenly through each of the first shielding lines 132, thus avoiding any impact on the shielding effect.

In an embodiment, the common electrode layer 181 further includes a plurality of second common lines 183 extending in the first direction X. The first common lines 182 extend in the second direction Y. Each of the data lines 141 further includes a second data segment 1412 extending from one end of the first data segment 1411 in the second direction Y. One end of each of the first common lines 182 is connected to a respective one of the second common lines 183, with an orthographic projection of the second data segment 1412 on the substrate 11 being overlapped with a portion of an orthographic projection of the second common line 183 on the substrate 11.

Specifically, the common electrode layer 181 includes a plurality of common electrode groups (not indicated in the figure). The common electrode groups are spaced apart and set in the second direction Y. Each of the common electrode groups includes a plurality of the common electrodes 181A arranged at intervals in the first direction X. Herein, the common electrode layer 181 further includes the plurality of second common lines 183. Each of the second common lines 183 is provided corresponding to a respective one of the common electrode groups, with the second common line 183 being connected with the corresponding common electrodes 181A, enabling the second common line 183 to connect in parallel with the plurality of the common electrodes 181A in the common electrode group.

In an embodiment, the common electrode layer 181 further includes a plurality of third common lines 184. Each of the third common lines 184 is disposed between two adjacent ones of the first common lines 182. Herein, one end of each of the third common lines 184 is connected to one of the first common lines 182, and another end of the third common line 184 is connected to another one of the first common lines 182.

Specifically, each of the third common lines 184 is spaced and set apart from the second data segment 1412. An orthographic projection of the third common lines 184 on the substrate 11 is not overlapped with an orthographic projection of the second data segment 1412 on the substrate 11. Each of the third common lines 184 connects two adjacent ones of the common electrode groups.

Further, referring to FIG. 6, which is a third schematic cross-sectional diagram of an display panel according to an embodiment of the present disclosure.

In the present embodiment, the structure of the array substrate is similar/identical to the structure of the array substrate provided in the above embodiments. For details, please refer to the description of the display panel in the above embodiments, and it is not repeated herein.

In the present embodiment, the array substrate 10 further includes at least one boss 191 provided between the substrate 11 and the source-drain layer 140. The boss 191 is arranged between two adjacent ones of the pixel electrodes 171A. Each of the data lines 141 includes a first data sub-line 141A provided on a top of the boss 191 and a second data sub-line 141B provided on a side wall of the boss 191.

Specifically, the array substrate 10 further includes the semiconductor layer 19 disposed between the first insulating layer 12 and the first passivation layer 15. The semiconductor layer 19 includes an active layer and the boss 191, thereby eliminating the need for providing an additional boss 191. This not only reduces product costs but also saves on manufacturing processes.

The orthographic projection of the first data segment 1411 on the substrate 11 covers an orthographic projection of the boss 191 on the substrate 11. The first data segment 1411 includes the first data sub-line 141A disposed on the top of the boss 191 and the second data sub-line 141B disposed on the side wall of the boss 191. Herein, the second data sub-line 141B is disposed on a side of the first data sub-line 141A adjacent to any of the pixel electrodes 171A, and the present embodiment does not impose specific restrictions in this regard.

It can be understood that in the present embodiment, by setting the orthographic projection of the first data segment 1411 on the substrate 11 to cover the orthographic projection of the boss 191 on the substrate 11, and setting the first data segment 1411 to include the first data sub-line 141A disposed on the top of the boss 191 and the second data sub-line 141B disposed on the side wall of the boss 191, a cross-sectional area of the first data segment 1411 is increased. This, in turn, reduces a resistance of the first data segment 1411, which is beneficial for reducing the delays of signals passing through the data lines 141, thereby enhancing the charging rate of the pixel electrodes 171A.

Further, in an embodiment, the first data segment 1411 is provided between two adjacent ones of the pixel electrodes 171A. Herein, a horizontal distance between the first data sub-line 141A and one of the pixel electrodes 171A is equal to a horizontal distance between the second data sub-line 141B and another one of the pixel electrodes 171A. This makes the structure of the first data segment 1411 symmetrical, which is beneficial for reducing an impedance of the first data segment 1411, further reducing the delays of signals passing through the data lines 141, increasing the effective charging time, and thereby enhancing the charging rate of the pixel electrodes 171A.

The present embodiment provides a mobile terminal. The mobile terminal includes a terminal body and a display panel. The terminal body and the display panel are integrated. The display panel includes the array substrate described in any of the above embodiments.

It can be understood that the array substrate has been described in detail in the above embodiments, and the description will not be repeated here.

In specific applications, the mobile terminal may be a display screen for devices such as a smartphone, a tablet computer, a laptop, a smart bracelet, a smart watch, smart glasses, a smart helmet, a desktop computer, a smart TV or digital camera, or may even be applied to electronic devices with flexible display screens.

Beneficial effects of the embodiments of the present disclosure are as follows.

The embodiments of the present disclosure provide an array substrate. By setting each of the data lines to include the first data segment disposed between two adjacent ones of the pixel electrodes, the orthographic projection of the first data segment on the substrate is not overlapped with the orthographic projection of the pixel electrode layer on the substrate, the orthographic projection of the first data segment on the substrate is not overlapped with the orthographic projection of the common electrode layer on the substrate, thereby reducing the parasitic capacitance between the data lines and the pixel electrodes, improving the signal crosstalk caused by the parasitic capacitance to the pixel electrodes. This reduces the parasitic capacitance between the data lines and the common electrodes, and decreases the delays in the signals passing through the data lines, thereby enhancing the charging rate of the pixel electrodes.

In the above embodiments, each embodiment has its own focus. Parts that are not described in detail in a certain embodiment can be referred to the relevant descriptions in other embodiments.

The above is a detailed introduction to an array substrate provided by the embodiments of the present disclosure. Specific examples are used herein to illustrate the principles and implementations of the present disclosure. The description of the above embodiments is merely used to help understand the method of the present disclosure and its core idea. At the same time, for a person of ordinary skill in the art, changes could be made in specific embodiments and scope of application based on the idea of the present disclosure. In summary, the contents of the specification should not be construed as a limitation of the present disclosure.

What is claimed is:

1. An array substrate, comprising:
a substrate;
a source-drain layer disposed at a side of the substrate, the source-drain layer including a plurality of data lines;
a pixel electrode layer disposed at a side of the source-drain layer away from the substrate, the pixel electrode layer including a plurality of pixel electrodes arranged at intervals;
a common electrode layer disposed at a side of the pixel electrode layer away from the substrate,
wherein each of the plurality of data lines includes a first data segment arranged between two adjacent ones of the plurality of pixel electrodes, with an orthographic projection of the first data segment on the substrate being not overlapped with an orthographic projection of the pixel electrode layer on the substrate, and the orthographic projection of the first data segment on the substrate being not overlapped with an orthographic projection of the common electrode layer on the substrate.

2. The array substrate of claim 1, wherein the pixel electrode layer includes a plurality of pixel electrode groups, each pixel electrode group being arranged between two adjacent ones of the plurality of data lines, and each of the pixel electrode groups includes two of the pixel electrodes,
wherein in each of the pixel electrode groups, either of the pixel electrodes is connected to one of the two adjacent data lines that is closer to the pixel electrode.

3. The array substrate of claim 2, wherein the array substrate further comprises a first metal layer disposed between the substrate and the source-drain layer, the first metal layer includes a plurality of first shielding lines, a direction of extension of the first shielding lines is the same as a direction of extension of the data lines;
wherein an orthographic projection of two adjacent ones of first shielding lines on the substrate is not overlapped with an orthographic projection of one of the data lines on the substrate, and is located on both sides of the orthographic projection of the data line on the substrate.

4. The array substrate of claim 3, wherein the orthographic projection of the common electrode layer on the substrate is not overlapped with the orthographic projection of the first shielding lines on the substrate.

5. The array substrate of claim 3, wherein the common electrode layer further includes a plurality of first common lines, the first metal layer includes a plurality of second shielding lines, each of the first common lines is provided corresponding to a respective one of the second shielding lines, the first common line and the second shielding line both being disposed between two adjacent ones of the pixel electrodes,
wherein an orthographic projection of the first common lines on the substrate covers an orthographic projection of the second shielding lines on the substrate, the first common lines being connected to the second shielding lines, respectively.

6. The array substrate of claim 5, wherein the first metal layer further includes a third shielding line, the third shielding line extending in a first direction, the first shielding lines and the second shielding lines both extending in a second direction,
wherein one end of each of the first shielding lines is connected to the third shielding line, one end of each of the second shielding lines is connected to the third shielding line, and another end of each of the second shielding lines is connected to a respective one of the first common lines, the first direction and the second direction forming a predetermined angle.

7. The array substrate of claim 5, wherein the common electrode layer further includes a plurality of second common lines, the second common lines extending in a first direction, and the first common lines extending in a second direction,
each of the data lines further includes a second data segment extending from one end of the first data segment in the second direction;
wherein one end of each of the first common lines is connected to a respective one of the second common lines, an orthographic projection of the second data segment on the substrate covering at least a portion of an orthographic projection of the second common line on the substrate.

8. The array substrate of claim 7, wherein the common electrode layer further includes a plurality of third common lines, each of the third common lines being disposed between two adjacent ones of the first common lines, wherein one end of each of the third common lines is connected to one of the first common lines, and another end of the third common line is connected to another one of the first common lines.

9. The array substrate of claim 1, wherein the array substrate further comprises at least one boss provided between the substrate and the source-drain layer, the boss being arranged between two adjacent ones of the pixel electrodes,
wherein each of the data lines includes a first data sub-line provided on a top of the boss and a second data sub-line provided on a side wall of the boss.

10. The array substrate of claim 1, wherein the array substrate further comprises a first passivation layer and a second passivation layer, the first passivation layer being disposed between the data lines and the pixel electrode layer, the second passivation layer being disposed between the pixel electrode layer and the common electrode layer.

11. A mobile terminal, comprising a terminal and a display panel, the terminal body and the display panel being integrated, the display panel comprising an array substrate, the array substrate comprising:
a substrate;
a source-drain layer disposed at a side of the substrate, the source-drain layer including a plurality of data lines;
a pixel electrode layer disposed at a side of the source-drain layer away from the substrate, the pixel electrode layer including a plurality of pixel electrodes arranged at intervals;
a common electrode layer disposed at a side of the pixel electrode layer away from the substrate,
wherein each of the plurality of data lines includes a first data segment arranged between two adjacent ones of the plurality of pixel electrodes, with an orthographic projection of the first data segment on the substrate being not overlapped with an orthographic projection of the pixel electrode layer on the substrate, and the orthographic projection of the first data segment on the substrate being not overlapped with an orthographic projection of the common electrode layer on the substrate.

12. The mobile terminal of claim 11, wherein the pixel electrode layer includes a plurality of pixel electrode groups, each pixel electrode group being arranged between two adjacent ones of the plurality of data lines, and each of the pixel electrode groups includes two of the pixel electrodes,
wherein in each of the pixel electrode groups, either of the pixel electrodes is connected to one of the two adjacent data lines that is closer to the pixel electrode.

13. The mobile terminal of claim 12, wherein the array substrate further includes a first metal layer disposed between the substrate and the source-drain layer, the first metal layer includes a plurality of first shielding lines, a direction of extension of the first shielding lines is the same as a direction of extension of the data lines;
wherein an orthographic projection of two adjacent ones of first shielding lines on the substrate is not overlapped with an orthographic projection of one of the data lines on the substrate, and is located on both sides of the orthographic projection of the data line on the substrate.

14. The mobile terminal of claim 13, wherein the orthographic projection of the common electrode layer on the substrate is not overlapped with the orthographic projection of the first shielding lines on the substrate.

15. The mobile terminal of claim 13, wherein the common electrode layer further includes a plurality of first common lines, the first metal layer includes a plurality of second shielding lines, each of the first common lines is provided corresponding to a respective one of the second shielding lines, the first common line and the second shielding line both being disposed between two adjacent ones of the pixel electrodes,
wherein an orthographic projection of the first common lines on the substrate covers an orthographic projection of the second shielding lines on the substrate, the first common lines being connected to the second shielding lines, respectively.

16. The mobile terminal of claim 15, wherein the first metal layer further includes a third shielding line, the third shielding line extending in a first direction, the first shielding lines and the second shielding lines both extending in a second direction,
wherein one end of each of the first shielding lines is connected to the third shielding line, one end of each of the second shielding lines is connected to the third shielding line, and another end of each of the second shielding lines is connected to a respective one of the first common lines, the first direction and the second direction forming a predetermined angle.

17. The mobile terminal of claim 15, wherein the common electrode layer further includes a plurality of second common lines, the second common lines extending in a first direction, and the first common lines extending in a second direction,
each of the data lines further includes a second data segment extending from one end of the first data segment in the second direction;
wherein one end of each of the first common lines is connected to a respective one of the second common lines, an orthographic projection of the second data segment on the substrate covering at least a portion of an orthographic projection of the second common line on the substrate.

18. The mobile terminal of claim 17, wherein the common electrode layer further includes a plurality of third common lines, each of the third common lines being disposed between two adjacent ones of the first common lines, wherein one end of each of the third common lines is connected to one of the first common lines, and another end of the third common line is connected to another one of the first common lines.

19. The mobile terminal of claim 11, wherein the array substrate further includes at least one boss provided between the substrate and the source-drain layer, the boss being arranged between two adjacent ones of the pixel electrodes,
wherein each of the data lines includes a first data sub-line provided on a top of the boss and a second data sub-line provided on a side wall of the boss.

20. The mobile terminal of claim 11, wherein the array substrate further includes a first passivation layer and a second passivation layer, the first passivation layer being disposed between the data lines and the pixel electrode layer, the second passivation layer being disposed between the pixel electrode layer and the common electrode layer.
